(19) United States
(12) Patent Application Publication
(10) Pub. No.: US 2025/0216786 A1
(43) Pub. Date: Jul. 3, 2025

(54) STRESS LAYER MODIFICATION USING ENERGETIC BEAM PROCESSING THROUGH PHOTORESIST MASK

(71) Applicant: Applied Materials, Inc., Santa Clara, CA (US)

(72) Inventor: Morgan EVANS, Manchester, MA (US)

(73) Assignee: Applied Materials, Inc., Santa Clara, CA (US)

(21) Appl. No.: 18/399,346

(22) Filed: Dec. 28, 2023

(51) Int. Cl. G03F 7/095; G03F 7/00; G03F 7/20

(52) U.S. Cl. CPC G03F 7/095; G03F 7/0035; G03F 7/2022

(57) ABSTRACT

A method may include providing a stress compensation stack on a main surface of the substrate, wherein the stress compensation stack comprises a patterned resist layer and a stress compensation layer, disposed subjacent the patterned resist layer. The patterned resist layer may be determined according to a surface map of the main surface of the substrate. The method may further include directing processing species to the stress compensation stack, wherein the stress compensation layer is selectively altered as a function of position across the substrate.

### FIELD

The present embodiments relate to stress control in substrates, and more particularly to stress compensation to manage substrate stress.

### BACKGROUND

Devices such as integrated circuits, memory devices, and logic devices may be fabricated on a substrate such as a semiconductor wafer by a combination of deposition processes, etching, ion implantation, annealing, and other processes. Often, complete fabrication of devices and related circuitry may entail many hundreds of operations, including dozens of lithography operations. In particular, lithographic operations may require that a given mask to fabricate structures in a given region or level is to be aligned to preexisting structures.

A resulting problem with fabrication of substrates is the development of out-of-plane distortion (OPD) caused by stresses within the wafer, which distortion may be referred to as warpage. This OPD may be a result of stress that develops within the wafer as a result of processing. As a result, management of OPD may be critical to achieve proper overlay between structures fabricated at different levels of a device. For example, a type of OPD often encountered is a global wafer curvature that may develop at many instances of processing due to stress buildup in the wafer as a result of processing operations. A related problem to OPD is so called in-plane distortion that relates to distortion within an X-Y plane of a substrate due to the X-Y-Z distortion characteristic of OPD.

One approach to managing wafer (substrate) stress is to provide a stress compensation layer on the back of a substrate, which layer may be used counteract existing stress within the substrate and thus reduce OPD. In particular implementations, ion implantation has been used to implant ions into the stress compensation layer in order to attempt to alter the stress state in the stress compensation layer and thus indirectly change the stress and OPD in the substrate.

In some approaches, blanket ion implantation may be performed to address a global curvature of a substrate, by altering the stress state in a stress compensation layer in a uniform manner across the substrate. In other approaches, a patterned implantation may be performed to address more varied OPD pattern in a substrate, such as a so-called potato chip curvature or saddle curvature. In known ion implantation approaches, an ion beam may be directed to scan different locations on a substrate to impart varying ion dose that varies according to substrate location.

At present, these approaches of implanting ion beams into stress compensation layers of a substrate may process substrates at the rate of ˜1-10 wafers per hour, which rate may be unduly slow for a commercial wafer fabricator. Moreover, patterned ion implantation approaches that employ scanning of an ion beam to generate an implant pattern may lack adequate spatial resolution to address complex patterns of OPD on a substrate, such as chip level variations that may be caused by processing operations performed to define circuitry on each die portion of a wafer.

With respect to these and other considerations the present embodiments are provided.

### BRIEF SUMMARY

In one embodiment, a method is provided. The method may include providing a stress compensation stack on a main surface of the substrate, wherein the stress compensation stack comprises a patterned resist layer and a stress compensation layer, disposed subjacent the patterned layer. The patterned resist layer may be determined according to a surface map of the main surface of the substrate. The method may further include directing processing species to the stress compensation stack, wherein the stress compensation layer is selectively altered as a function of position across the substrate.

In another embodiment, an ion implanter may include an ion source to generate an ion beam; a beamline component to vary a scanning of the ion beam; and a controller that includes a processor, and a memory unit coupled to the processor, including a scanned implant routine. The scanned implant routine operative on the processor to control the ion implanter to: receive a surface map of a substrate; and impart an implant pattern into a stress compensation layer on the substrate by performing a scanned implant based upon the surface map.

In a further embodiment, a controller for an ion implanter may include a processor; and a memory unit coupled to the processor, including a scanned implant routine. The scanned implant routine may be operative on the processor to control an ion implanter to: receive a surface map of a substrate; and impart an implant pattern into a stress compensation layer on the substrate by performing a scanned implant based upon the surface map.

### BRIEF DESCRIPTION OF THE DRAWING

FIG. 1A shows an exemplary ion implantation system in accordance with the present disclosure;

FIG. 1B shows further details of a controller according to some embodiments of the disclosure;

FIG. 2A shows an example of a wafer map that maps a surface of a substrate that exhibits a pattern of OPD;

FIG. 2B shows an exemplary gray tone resist pattern for managing the stress in the substrate of FIG. 2A;

FIG. 3A to FIG. 3G depict exemplary stages in processing a substrate to reduce OPD according to some embodiments of the disclosure;

FIG. 3H illustrates an embodiment for processing a stress compensation layer;

FIG. 4A and FIG. 4B show two stages of processing a gray tone resist to generate a variable resist layer thickness, according to one embodiment;

FIG. 5A depicts another embodiment using a digital implant mask for substrate-level stress management;

FIG. 5B depicts another embodiment using a digital implant mask for chip-level stress management;

FIG. 6A is a graph that presents a three dimensional surface map of a portion of a substrate at the chip level;

FIG. 6B is an illustration that depicts a three dimensional surface map of a an entire substrate, showing a repeated pattern of OPD corresponding to 24 different chip regions;

FIG. 6C depicts a top view of the substrate of FIG. 6B using a gray tone mask to process the repeated pattern of OPD;

FIG. 6D depicts a side view of the arrangement of FIG. 6C;

FIG. 6E depicts ribbon beam processing of a gray tone resist pattern developed on the substrate of FIG. 6B after the instance of FIG. 6C;

FIG. 6F depicts an example of non-uniform scanning of a processing beam;

FIG. 6G depicts a three dimensional surface map of the substrate of FIG. 6B after the processing of FIG. 6E and after subsequent removal of gray tone resist;

FIG. 7 illustrates an exemplary process flow;

FIG. 8 illustrates an exemplary process flow; and

FIG. 9 illustrates an exemplary process flow.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The embodiments described herein relate to techniques and apparatus for improved substrate stress management, and the related management of out-of-plane distortion (OPD). The present embodiments present an approach that employs energetic beam processing or energetic particle processing in conjunction with patterned photoresist (“resist”) layers and stress control layers to control the distribution of damage within a stress control layer within the X-, Y-, and Z-directions, and thus control OPD with better accuracy and resolution on a substrate.

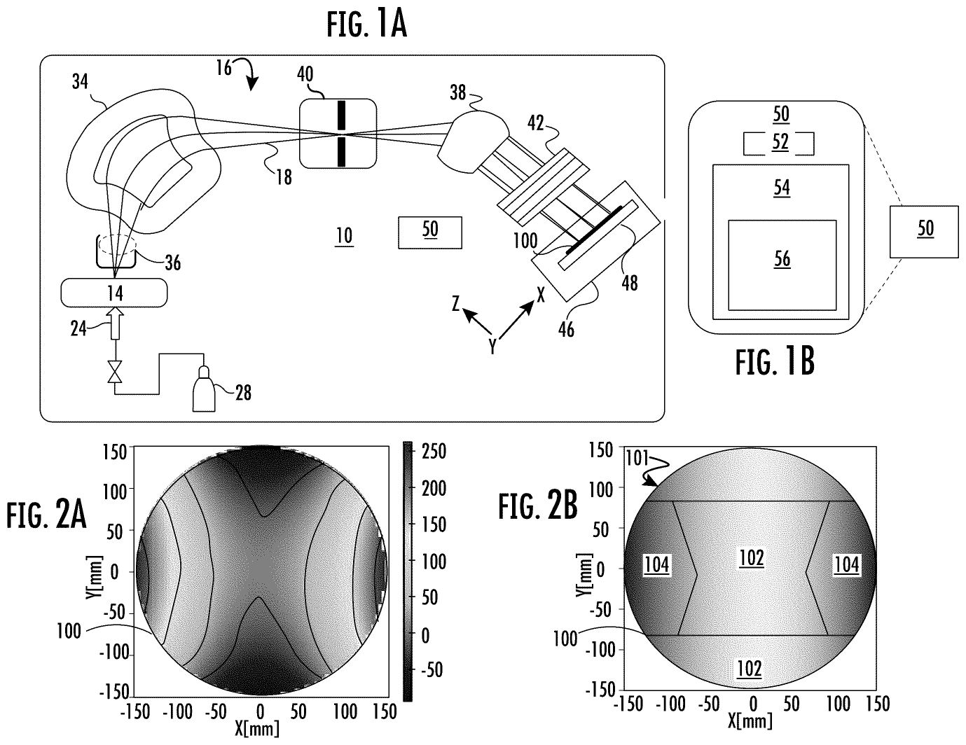

Referring now to FIG. 1A, an exemplary system in accordance with the present disclosure is shown. The ion implantation system (hereinafter “system”) 10 represents a beamline containing, among other components, an ion source 14 for producing an ion beam 18, an ion implanter, and a series of beam-line components 16. The ion source 14 may comprise a chamber for receiving a flow of gas 24 and generating ions therein. The ion source 14 may also comprise a power source and an extraction electrode assembly disposed near the chamber. Although non-limiting, the ion source 14 may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art. As shown, there may be one or more feed sources 28 operable with the chamber of the ion source 14. In various embodiments, different species may be used as the ions to be used to process the stress in the film. Non-limiting examples of suitable ions include silicon (Si), boron (B), carbon (C), oxygen (O), germanium (Ge), phosphorus (P), arsenic (As), argon (Ar), krypton (Kr), neon (Ne), and krypton (Kr) and so forth, so as to control substrate stress.

The beam-line components 16 may include, for example, a mass analyzer 34, a first acceleration or deceleration stage 36, a collimator 38, a mass resolving slit 40, and other suitable downstream beamline components such as an energy filter 42, to accelerate the ion beam 18, decelerate the ion beam 18, shape the ion beam 18, scan the ion beam 18, and so forth. In particular embodiments, the beam-line components 16 may filter, focus, accelerate, decelerate, and otherwise manipulate ions or the ion beam 18 to have a desired species, shape, energy, and other qualities. The ion beam 18 passing through the beam-line components 16 may be directed toward a substrate mounted on a platen or clamp within a process chamber 46. As appreciated, the substrate may be moved in one or more dimensions (e.g., translate, rotate, and tilt).

According to various embodiments of the disclosure, the ion source 14 may generate the ion beam 18 for processing a substrate by implanting into a patterned layer in order to reduce OPD in the substrate. In various embodiments, the ion beam (in cross-section) may have a targeted shape, such as a spot beam or ribbon beam, as known in the art. In the Cartesian coordinate system shown, the direction of propagation of the ion beam 18 may be represented as parallel to the Z-axis, while the actual trajectories of ions with the ion beam 18 may vary. In order to process the substrate, the ion beam 18 may be accelerated to acquire a target energy by establishing a voltage (potential) difference between the ion source 14 and the wafer (substrate). In particular embodiments, the ion beam 18 may be a ribbon beam that is elongated along x direction, so as to cover an entirety of the substrate 100 along the x-direction. As further shown in FIG. 1, the system 10 may include a controller 50 to control operation of various components of the system 10, including components to scan the platen 48, to tilt the platen 48, to scan the ion beam 18, or to adjust the energy of the ion beam 18, for example. FIG. 1B provides details of an embodiment of the controller 50, discussed further below. In this manner, the ion beam 18 and/or the platen 48 may be scannable along the Y-direction to expose an entirety of the substrate 100.

FIG. 2A shows an example of a wafer map that plots a surface of a substrate 100 that exhibits a pattern of OPD. The OPD as shown in FIG. 2A may be a reflection of non-uniform stress within the substrate 100, thus generating a pattern of substrate curvature that is, at least in part, caused by the non-uniform stress. The OPD of FIG. 2A is characterized by a downwardly displaced substrate surface at the top and bottom areas along the y-axis, and an upwardly displaced substrate surface at the extreme left and extreme right areas along the X-axis, imparting a saddle shape to the substrate in three dimensions. The center of the substrate 100 may be deemed to lie at 0 point along the z-axis. For the 300 mm diameter wafer shown (substrate 100), the maximum downward OPD with respect to 0 is approximately 90 micrometers, while the maximum upward OPD (to the left and right) is approximately 263 micrometers

FIG. 2B shows an exemplary gray tone resist pattern (for brevity, the word ‘resist’ as used herein will refer to photoresist, unless otherwise noted) for managing the stress in the substrate of FIG. 2A. The resist pattern 101 may be generated so as to provide a mask that is used in conjunction with ion implantation to reduce or eliminate the OPD as shown in FIG. 2A. In this example, the resist pattern 101 may represent a gray tone resist pattern that is formed using a gray tone resist. For the purposes of simplicity of explanation, the resist pattern 101 is shown as having a plurality of distinct regions, shown as gray tone regions 102. However, the present embodiments cover more complex patterns of resist as detailed below. The resist pattern 101 may include block regions 104, as well as gray tone region 102. These regions may be designed to attenuate more or less ions of an ion beam to be used to implant into a stress compensation layer (not visible) of the substrate 100 that lies subjacent to the resist pattern 101.

In one non-limiting example, the block regions 104 may include resist having a uniform thickness that is adequate to block an entirety of ions of an ion beam from impinging upon the stress compensation layer. The gray tone region 102 may be defined by resist regions having thickness that varies as a function of location across the substrate (in the X-Y plane), as well as regions where the resist is completely removed. In one implementation, when the resist pattern 101 is exposed to an ion beam, the ion beam will generate an implant pattern within a stress compensation layer that alters the stress state in the stress compensation layer in a manner to reduce or eliminate the OPD pattern shown in FIG. 2A.

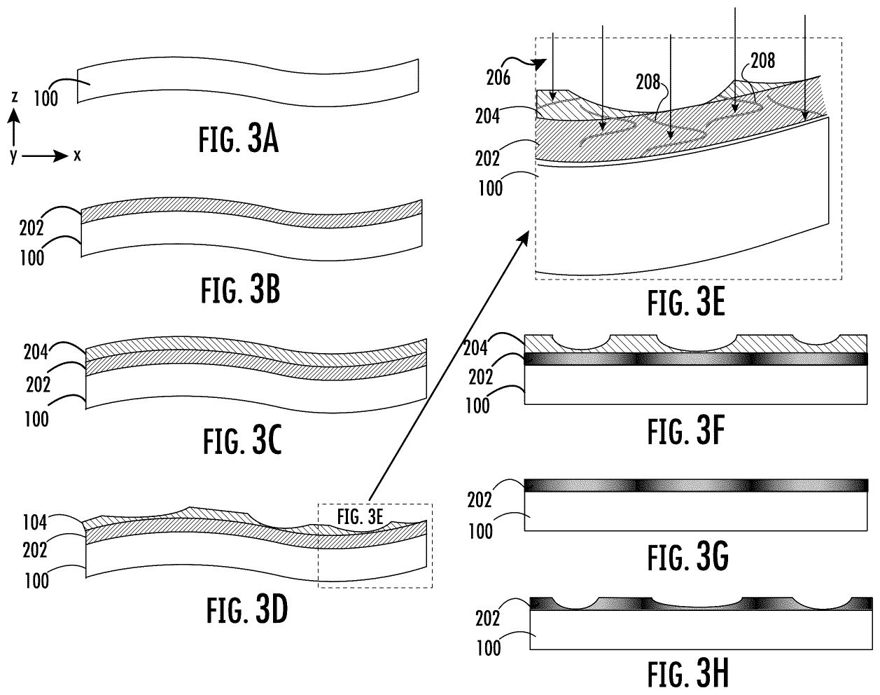

To further detail the management of substrate stress using gray tone resist patterning in conjunction with ion implantation, FIG. 3A to FIG. 3G depict exemplary stages in processing a substrate to reduce OPD according to some embodiments of the disclosure. At FIG. 3A there is shown a substrate 100, which substrate may be a silicon wafer. The substrate 100 may exhibit a curvature, including an OPD characterized by a complex pattern of warpage in some embodiments. In the example shown, the substrate is shown in cross-section, such as within an X-Z plane of the Cartesian coordinate system shown, but the relative dimensions in terms of width and substrate thickness and curvature may not be drawn to scale. For example, the substrate 100 may represent a wafer having a diameter along the main surface of 200 mm, 300 mm, or other size according to some non-limiting embodiments. The thickness of the substrate 100 may be on the order of several hundred micrometers in some embodiments. Moreover, the maximum OPD exhibited by the substrate 100, which OPD may be expressed in terms of deviation from a nominally flat X-Y plane, may be on the order of a few hundreds of micrometers.

At FIG. 3B, a subsequent instance is shown where a stress compensation layer 202 has been formed on a main surface of the substrate 100. The stress compensation layer 202 may be a known stress compensation layer material, such as an oxide layer or a nitride layer according to some non-limiting embodiments, including silicon nitride (hereinafter referred to also as “SiN”). As such, the stress compensation layer 202 may or may not alter the overall stress state of the substrate 100 substantially, and thus the pattern of OPD exhibited in FIG. 3A may persist, as suggested in FIG. 3B.

At FIG. 3C, a subsequent instance is shown where a blanket photoresist layer, termed a gray tone resist layer 204, has been applied to the stress compensation layer 202. The gray tone resist layer 204 may be composed of a known resist material such as a suitable gray tone resist material. The formation of the gray tone resist layer 204, having a low elastic modulus, may generate little or no change to the overall stress state of substrate 100, and thus the OPD as exhibited at FIG. 3A may persist.

At FIG. 3D there is shown a subsequent instance where the gray tone resist layer 204 has been processed into a patterned resist layer that exhibits a variation in film thickness (meaning the thickness along the Z-axis, as a function of position along the X-Y plane. This variation in resist thickness may or may not generate exposed regions where the upper surface of the subjacent layer, stress compensation layer 202, is exposed. Again, the patterning of the gray tone resist layer 204 may exert little or no effect on the pattern of OPD on substrate 100.

In various embodiments, discussed further below, the patterning of the gray tone resist layer 204 may be chosen to provide an implantation mask for a subsequent ion implantation process that is to be performed. The exact pattern of the implantation mask (meaning the patterned gray tone resist layer) may be chosen, for example according to the pattern of OPD exhibited by the substrate 100, for example, at the stage of FIG. 3C. In different embodiments, the patterning of the gray tone resist layer 204 may be accomplished by exposing the gray tone resist layer to radiation through a gray tone lithography mask that exhibits a suitable pattern based upon the pattern of OPD. In some examples, discussed further below, a resist mask process may be a digital process. After exposure to radiation, the gray tone resist layer 204 may be developed, resulting in the structure of FIG. 3D. The gray tone lithography mask may be particularly selected to vary the degree of exposure of the gray tone resist layer 204 to radiation, as a function of position along the X-Y plane. As a result, the depth of the gray tone resist layer 204 that is altered by the radiation will vary along the X-Y plane, such that the final thickness of the gray tone resist layer 204 after a subsequent development process may vary. Known gray tone resist masks may provide the ability to vary resist layer thickness as a function of location along the X-Y plane at the scale down to 100 nm or less. Thus, at the lateral (X-Y) scale of micrometers or greater, the variation in thickness of gray tone resist layer 204 may appear smooth.

In some embodiments the gray tone mask used to pattern gray tone resist layer 204 may be an imprint mask that is applied directly to gray tone resist layer 204 to generate the structure as shown in FIG. 3D.

Turning to FIG. 3E there is shown a subsequent instance when the substrate 100, including stress compensation layer 202 and the gray tone resist layer 204, after patterning, is exposed to an ion implantation process, denoted by ion beam 206. The ion beam 206 may be selected to have a suitable ion energy for implantation into substrate 100, so as to alter the stress state in particular within the stress compensation layer 202. In the operation depicted at FIG. 3E, the ion beam 206 is shown as a plurality of ions whose trajectories are shown by the vertical arrows. Because the ions may exhibit a similar energy across ion beam 206, the depth of implantation of ions into stress compensation layer 202 in particular is determined by the local thickness of the gray tone resist layer 204 as a function of position within the X-Y plane. As a result, some areas of the stress compensation layer 202 will receive relatively greater dose of ions than other areas, as suggested by the implant profiles 208 that are associated with the different ion positions in FIG. 3E. Thus, some of the implant profiles 208 may be totally contained within the gray tone resist layer 204 at locations where the gray tone resist layer 204 is sufficiently thick; in other regions, the implant profiles may extend to a lesser or greater amount into the stress compensation layer. As a result, the amount of implant damage and therefore the stress state within stress compensation layer 202 will be selectively varied as a function of X-Y location after the implantation procedure of FIG. 3E.

Turning to FIG. 3F there is shown a subsequent instance after the implant process of FIG. 3E is complete, where the stress state of the stress compensation layer has been selectively modified within the X-Y plane. As a result, by appropriate mask selection, and selection of ion beam parameters, the stress compensation layer 202 exhibits a pattern of implantation damage that reflects the pattern of the gray tone resist layer 204, causing the original OPD of FIG. 3A to be reduced or removed, as suggested in FIG. 3F.

At FIG. 3G, a subsequent stage of processing is shown where the gray tone resist has been selectively removed, such as by ashing. Note that the stress compensation layer 202, having a non-uniform implantation pattern, remains. Thus, this non-uniform implant pattern and resulting non-uniform stress pattern continue to exert a force on substrate 100 that maintains the substrate with less OPD.

In alternative embodiments, at the stage of processing shown in FIG. 3E the energy of the ion beam 206 may be tailored to generate substantial etching of the stress compensation layer 202, in areas where the gray tone resist has been completely removed or in areas where gray tone resist is relatively thinner so as to allow penetration of ions into the stress compensation layer 202. FIG. 3H illustrates an embodiment where the stress compensation layer 202 has been exposed to an energetic beam so as to selectively etch the stress compensation layer 202 in regions where the gray tone resist layer is absent or relatively thinner. Thus, a patterned stress compensation layer is formed that has a pattern or etched regions. The patterned etch regions may be designed to selectively alter the stress state in the stress compensation layer 202 as a function of position in the X-Y plane, and thus to selectively alter the stress state in the subjacent substrate, meaning the substrate 100. In this manner, a pattern of stress may be imparted into the substrate 100 so as to reduce the pre-existing OPD.

In different embodiments, the selective etching of the stress compensation layer 202 as depicted in FIG. 2H may be performed by an inert ion beam, a reactive ion beam, a radical beam generated from a plasma for example, by immersion in a plasma chamber, or by chemical etching.

According to different embodiments of the disclosure, a gray tone resist layer may be processed using a gray tone lithography mask having a pattern that is tailored so as to generate a variable thickness in the gray tone resist layer over a suitable length scale to counteract an initial substrate OPD. For example, for curvature that generates significant OPD at the wafer level (many centimeters in the X-Y plane) or at the chip level (many millimeters in the X-Y plane), stress control within the substrate may be needed at the sub-millimeter range along the X-Y plane to reduce such curvature. Thus, in various embodiments, gray tone resist layers may be fabricated having features whose thickness is tailored to change substantially over the millimeter length scale, the hundred micrometer scale, the micrometer scale, or hundred nanometer scale. Such features are readily fabricated according to present day gray tone resist technology.

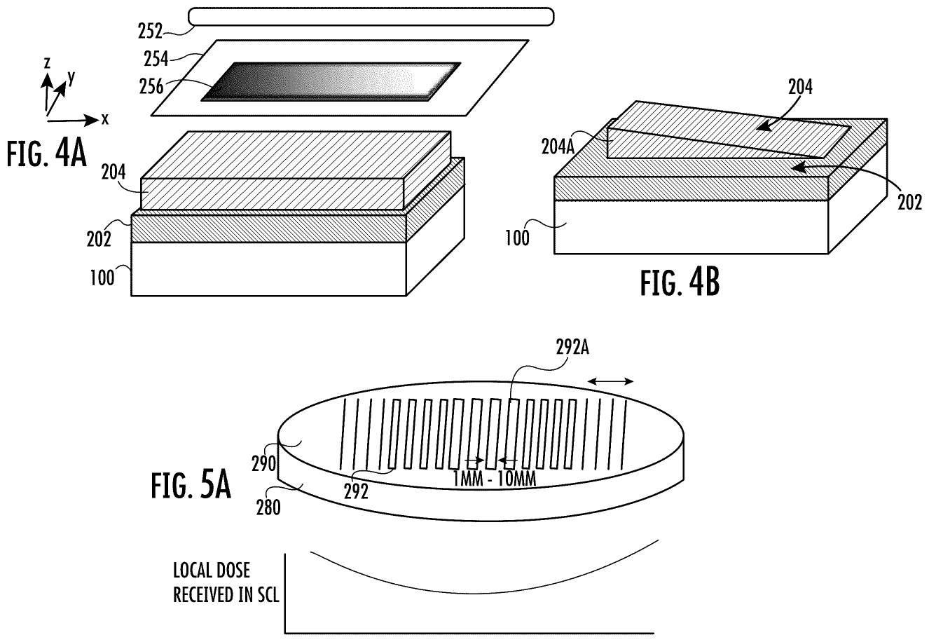

In one approach, as previously noted, gray tone resist may be processed using a gray tone mask that is exposed to a suitable radiation to generate the desired pattern of gray tone resist. FIG. 4A and FIG. 4B show two stages of processing a gray tone resist to generate a variable effective thickness of a resist layer, according to one embodiment. In this example, an illumination source 252 is used to expose substrate 250, having stress compensation layer 202 and gray tone resist layer 204 disposed thereon. As in known approaches a diffuser (not separately shown) may be optionally included between illumination source 252 and substrate 250. A gray tone mask 254 is disposed between gray tone resist layer 204 and illumination source 252, to partially attenuate radiation from the illumination source 252 in order to generate an exposed pattern in gray tone resist layer 204. The gray tone mask 254 may include a patterned region 256 that is composed of sub-features whose arrangement is such as to attenuate radiation passing through the gray tone mask in a smoothly varying fashion along the X-Y plane. For example, the feature size of patterning features in the patterned region 256 may be designed according to the wavelength of radiation. For illustration purposes the dimensions of the patterned region shown along the X- and Y-direction may be any suitable distance, such as comparable to wafer diameter, comparable to chip (die) size on a wafer being processed, or at a sub-millimeter length. As suggested in FIG. 4A, the attenuation of radiation in patterned region 256 is greater to the left side and lesser to the right side. In the case of a positive resist, this circumstance will lead to regions of gray tone resist layer 204 that are disposed to the right being more soluble to developer than those regions to the left. As a result, after the exposure in FIG. 4A, and subsequent development, a patterned feature 204A is formed in gray tone resist layer 204, as shown in FIG. 4B. In this example, the patterned feature 204A has a wedge shape where the thickness smoothly changes along the X-direction. However, by suitable design of a patterned gray tone lithography mask, any suitable shape, including three dimensional shapes, may be imparted to the gray tone resist layer 204.

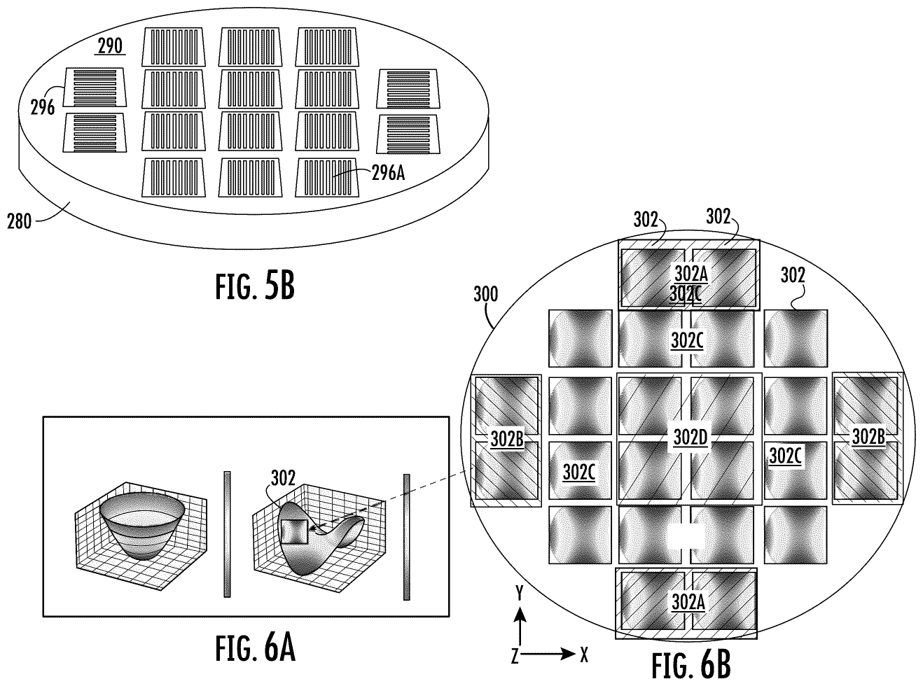

In additional embodiments of the disclosure, a non-gray tone resist layer, such as a known resist with ‘binary’ response, may be patterned to facilitate selective altering of a subjacent stress compensation layer. FIG. 5A depicts another embodiment where a resist layer is patterned to generate a mask that acts as an implantation or etch mask so as to selectively pattern a subjacent stress compensation layer. In this example, a resist layer, such as a binary resist, has been patterned to form a digitally-patterned resist layer, shown as resist layer 292, where the resist layer 292 partially covers a stress compensation layer 290. In one suitable example of digital resist pattern, a series of lines may be formed in the resist layer 292, where a fixed pitch is implemented between adjacent lines. In order to vary the opacity of the digitally patterned resist layer, resist layer 292, and thus vary the degree of exposure of the stress compensation layer 290 to implanting ions or to etching species, the duty cycle (linewidth) of the lines forming the pattern 292A may be varied as a function of location across the substrate 280. In one example, as particularly shown in FIG. 5A, the duty cycle applied to a pulsed deposition beam may be varied of the resist layer 292 so as to increase toward the middle of the substrate 280. Because the linewidth is relatively larger toward the middle of substrate 280, the dose of energetic species that may impact the stress compensation layer 290 in the middle of substrate 280 is relatively lower as opposed to the dose toward the edges of substrate 280, as shown in the graph. In one example, where a substrate is a 300 mm wafer, having a thickness on the order of 500 μm to 800 μm, this variation of dose implanted into the stress compensation layer 290 over the substrate 280 as a function of position may counteract a global curvature (meaning a wafer level variation, as opposed to a local variation at the chip level, for example) of the substrate 280. Note that in a pattern of resist layer 292 the line pitch may be on the order of 1 μm to 10 μm, so that the linewidth will vary over a similar range depending upon duty cycle. Moreover, the resist layer 292 may be arranged as a series of fields that have uniform duty cycle (meaning uniform linewidth) for the resist lines contained therein, where the fields of lines have a width on the order of 1 mm to 10 mm. Thus, an individual field of lines may include ˜1000 lines of uniform width where the ion dose received in stress compensation layer 290 from an ion beam processing the substrate 300 is uniform. Accordingly, the average ion dose received in the substrate 280 may vary in steps of 1 mm-10 mm width across substrate 280. However, this step variation on the ˜1 mm length scale may nonetheless generate a continuous change in the effect on substrate 280.

In another example as shown in FIG. 5B, a digitally patterned resist layer is shown as resist layer 296, and is formed of a series of chip-scale fields, shown as fields 296A, which fields have the dimension of chips such as 1 cm or 2 cm on a side. Within a field 296A, the patterning may proceed with a digitally varying duty cycle at fixed pitch, as described above to account for chip level OPD or curvature of the substrate 300.

In the aforementioned embodiments, a gray tone resist process may be used in conjunction with ion implantation in order to generate an implant pattern that generates a variable amount of damage as a function of location across a substrate. Note that such a gray tone resist layer may include, in addition to regions where resist thickness varies, large macroscopic regions (on the order of centimeters or millimeters) where resist thickness, and thus implant damage does not vary. As noted, the exact pattern of such a gray tone resist layer may be dictated by the pattern of OPD as measured on a substrate at the time of formation of a stress compensation layer, for example. In fabrication of semiconductor or electronic devices on a substrate such as a silicon wafer, the wafer may be processed in a manner to generate an array of similar or identical chip regions, to be subsequently cut into individual semiconductor die. As a result, during processing, a repeatable pattern of device and circuit features may be formed across a substrate, where this repeatable device pattern generates a concomitant repeatable stress or OPD pattern within the substrate. In other examples, an array of chip patterns may be produced on a wafer where the chip patterns vary among each other. In either circumstance, the variation of OPD across a wafer may exhibit a signature at the length scale of an individual chip, such as a few millimeters to a few centimeters.

To address these circumstances, the present embodiments include approaches to pattern a gray tone resist layer to mimic the OPD pattern in a wafer that has been processed to define an array of chip regions.

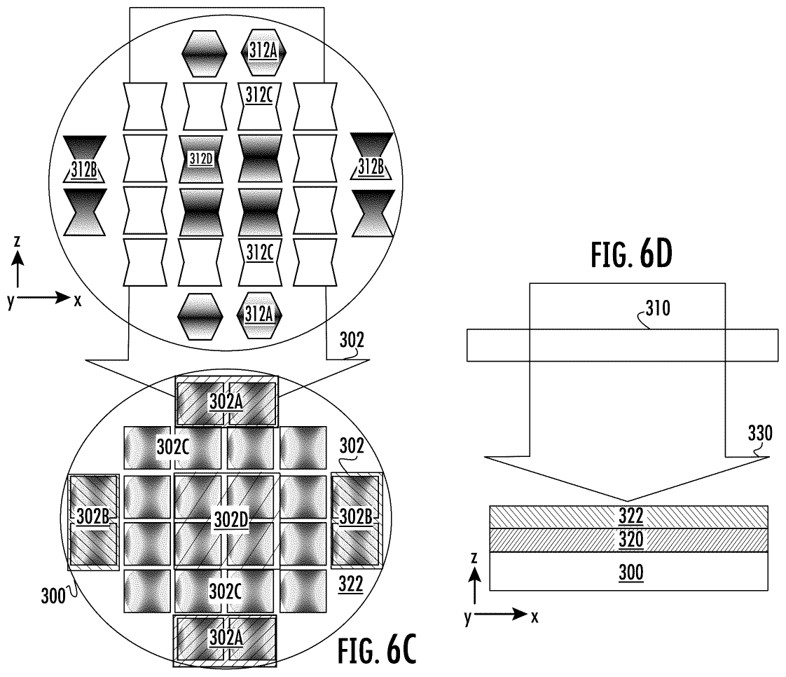

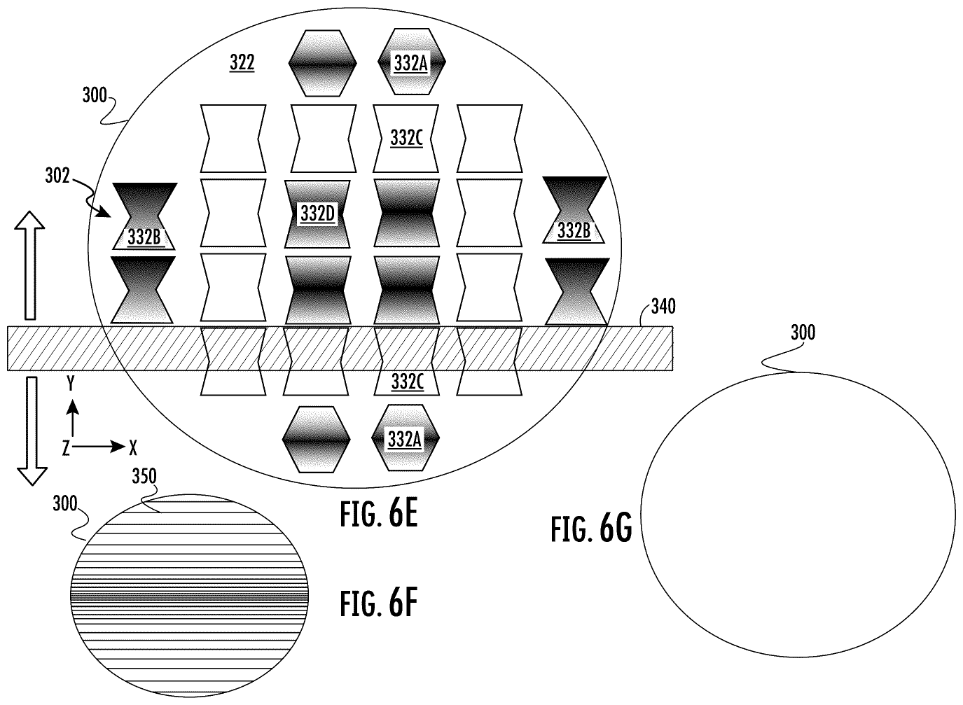

FIG. 6A is a graph that presents a three dimensional surface map of a portion of a substrate at the chip level. In this example, an array of 24 rectangular regions, shown as chip regions 302 are defined on a surface of the substrate 100. FIG. 6B is an illustration that depicts a three dimensional surface map of an entirety of a substrate 300, showing a repeated pattern of OPD corresponding to 24 different repeats of the chip regions 302 of FIG. 6A. The FIG. 6A shows that the chip region 302 has a saddle shape, as discussed previously. The substrate 300 may correspond to a 300 mm diameter silicon wafer for example. As such, each of chip regions 302 may have a dimension in the X- or Y-direction of 40 mm, for example. Note that in this example, the three dimensional pattern of OPD is essentially the same in each of chip regions 302. Said differently, on the surface of the substrate 300 a series of 24 different rectangular regions exhibit a repeated pattern of OPD that varies on the length scale of a millimeters to centimeters. In order to flatten the substrate to reduce such a pattern of OPD, gray tone mask may be designed having a suitable pattern that is arranged to facilitate selective patterned implantation into the substrate 300.

In known patterning of wafers, the chip level processing to generate repeated device chip patterns, such as the 24 different chip regions shown, may also cause variations in the degree of local OPD for example, that varies according to chip location on the wafer. Thus, the chip regions 302 may be further grouped according to location on the substrate 300. For purposes of illustration a grouping of four different chip regions is shown where the grouping is symmetrical with respect to the center of the substrate 300. In FIG. 6B, these four different regions are shown as region 302A, region 302B, region 302C, and region 302D.

In accordance with embodiments of the disclosure, an implant pattern may be added to chip level resist patterns to control wafer bow to within the requirements for subsequent device processing, which bow may be on the order of 100 μm across a full width of substrate 300 and ˜50 times smaller at the chip level.

FIG. 6C depicts a top view of the substrate of FIG. 6B using a gray tone mask to process the repeated pattern of OPD of FIG. 6B. FIG. 6D depicts a side view of the arrangement of FIG. 6C. The gray tone mask 310 may be designed generally according to the principles discussed above, in particular with respect to FIG. 4A and FIG. 4B. In this example, the gray tone mask 310 includes an array of 24 features, shown as features 312, having a feature shape that is merely shown for purposes of illustration. The features 312 themselves may include a resist feature or set of features having varying thickness within the X-Y plane. Note that the features of the mask 310 may be sized and spaced so as to overlay the chip regions 302 in substrate 300 when the gray tone mask 310 is aligned over the substrate 300. In FIG. 6C, radiation 330 may be directed through the mask 310 to expose the substrate 300, while a blanket coating of the gray tone resist layer 322 and stress compensation layer 320 are present, as further shown in FIG. 6D. Alternatively, a gray tone mask feature having the size of an individual one of chip regions 302 may be stepped over the substrate 300 to individually expose the chip regions 302.

As further illustrated in FIG. 6C, the features 312 may be varied in some aspects according to location on the gray tone mask 310. As an example, following the pattern of chip regions 302, the features 312 may be grouped into four different groups according to locations, such as region 312A, region 312B, region 312C, and region 312D. These four different regions may vary between each other in terms of the exact pattern of features 312, so as to address local differences in the pattern or amount of OPD between the different ones of the regions 302A-302D on the substrate 300.

FIG. 6E depicts a gray tone resist pattern 332 that is developed within the gray tone resist layer 322 on the substrate 300 of FIG. 6B after the instance of FIG. 6C. Subsequently, an ion implantation process may be performed where an ion beam is directed to the substrate 300 to selectively implant into the stress compensation layer 320 according to the gray tone resist pattern 332. Because the gray tone resist pattern 332 exhibits a regular array of features that overlay the respective features 312, the implantation pattern within the stress compensation layer 320 will reflect a similar pattern. Thus, the pattern of implant damage and stress relief in substrate 300 will be tailored to mimic the original OPD pattern and thus flatten the substrate locally within each or features 312. Note that the approach outlined in FIGS. 6A-6E facilitates for a more simple and rapid implantation process that may effectively reduce a complex OPD pattern in a substrate.

As further illustrated in FIG. 6E, the gray tone resist pattern 332 may be varied in some aspects according to location on the gray tone mask substrate 300. As an example, following the pattern of chip regions 302, the final pattern of the gray tone resist pattern 332 may be grouped into four different groups according to locations, such as region 332A, region 332B, region 332C, and region 332D. These four different regions may vary between each other in terms of the exact pattern of resist features, so as to address local differences in the pattern or amount of OPD between the different ones of the regions 302A-302D on the substrate 300.

For example, FIG. 6E also depicts an embodiment where a ribbon processing beam having the width of the substrate 300 may be scanned along the Y-direction to expose the entirety of the substrate 300 to processing species, such as ions. Note that in some implementations, the processing beam may be an ion beam 340 that is held be held stationary with respect to the Y-direction, while the substrate 300 is scanned along the Y-direction. In some variants, the ion beam 340 may be a scanned spot beam that is scanned along the X-direction rapidly at a frequency of ˜1 kHz or greater, to generate a ribbon beam shape, as shown, while scanning of the substrate 300 takes place at a relatively slower rate, such as several centimeters per second for a 30 cm wafer. In some examples, the substrate 300 may be scanned back and forth along the Y-direction. After the scanning of the substrate and/or the scanning of the ion beam 340 over the substrate 300, the ions of ion beam 340 will be selectively implanted into the substrate according to the pattern of the gray tone resist pattern 332, including any variations between regions 332A, region 332B, region 332C, and region 332D. This implantation may result in selective stress change within the stress compensation layer 320 by selective implantation of ions into different areas of the stress compensation layer 320 as defined by the features according to the gray tone resistance pattern. As a result, upon exposure to the ion beam 340, those chip regions that receive the ion beam may have reduced OPD. Thus, selective and precise modification of the original OPD pattern of substrate 300 may be accomplished in a simple ion exposure process. In one example, the OPD of substrate 300 in FIG. 6A may be removed at the global level across the substrate 300 as well as at the chip level, resulting in a smooth featureless OPD pattern after removal of resist, as shown at FIG. 6G.

In further embodiments of the disclosure, scanned selective ion implantation may be employed together the aforementioned use of a gray tone resist mask, in order to control substrate stress and OPD. As an example, instead of imparting a uniform ion dose across a substrate, an ion beam, such as a ribbon ion beam, may be scanned in a non-uniform manner with respect to a substrate in order to additionally vary the effective ion dose that is imparted into a substrate. Non-uniform scanning may refer to the circumstance where the speed of scanning of the substrate with respect to the ion beam is varied as a function of beam location on the substrate, as an example. This non-uniform scanning of the substrate with respect to an ion beam may be combined with the variable thickness pattern of a gray tone resist in order to impart a more complex pattern of implant damage into a stress compensation layer that is subjacent to the gray tone resist layer. In some examples, where the ion beam may be directed to the substrate along a Z-axis, the substrate may additionally be rotated about a Z-axis between scans, may be tilted between scans, may be tilted and rotated between scans, and so forth. In embodiments of an ion beam that is provided as a scanned spot beam that is scanned along the X-direction at a frequency on the order of 1 kHz or more, the scan speed of the scanned spot beam may be varied as a function of location along the X-direction, together with scanning of the substrate along the Y-direction, in order to impart a non-uniform ion dose as a function of location in the X-Y plane. The embodiments are not limited in this context.

In these latter embodiments, an ion implanter that is used to implant a substrate may receive a set of substrate information, including OPD information of the substrate before processing in order to determine an appropriate processing routine to impart the suitable implantation pattern to reduce or eliminate the OPD. In addition to OPD information, the substrate information may include a gray tone resist pattern that is to be applied to the substrate. The substrate information may then be used to determine the ion beam processing routine parameters that are tailored to reduce the OPD according to the specific OPD pattern and the designed gray tone resist pattern. Such processing parameters may include non-uniform beam scanning conditions, including variation of scan speed of a scanned spot beam, variation of scan speed of a scanned substrate, rotation of the substrate, tilting of the substrate, and so forth. One example of a non-uniform implant pattern that may be employed by a scanned ion beam is beam scan pattern 350, also shown in FIG. 6F, where the beam dose may be increased towards the middle of a substrate 300, as shown.

Returning to the example of FIG. 6A-6F, in other embodiments, the gray tone resist pattern 332 may be formed in manner that the regions 332A, region 332B, region 332C, and region 332D all exhibit the same pattern. Instead, to account for local variations in OPD between regions 302A-302D, a non-uniform beam scanning operation may be performed, where a processing beam, such as an ion beam, is scanned differently with respect to substrate 300, in accordance with the different regions 332A-332D. Thus, scanning of a beam may such that less ion dose is directed toward region 332D as opposed to region 332A, and so forth. As a result, upon exposure to the ion beam 340, when scanned in a non-uniform manner over the gray tone resist pattern 332 (when the gray tone resist pattern does not vary among regions 332A-332D) those chip regions that receive the ion beam may have reduced OPD, as suggested in FIG. 6G. Thus, selective and precise modification of the original OPD pattern of substrate 300 may be accomplished in a patterned ion exposure process. In one example, the OPD of substrate 300 in FIG. 6A may be removed, resulting in a smooth featureless OPD pattern after removal of resist, as shown at FIG. 6G.

In further embodiments, to reduce OPD globally and locally across a substrate 300, the gray tone resist pattern 332 may be arranged such that the patterning is different in between the different regions 332A-332D, and a non-uniform beam scanning process may be performed upon the gray tone resist pattern 332. More generally, according to various embodiments of the disclosure, a non-uniform beam scanning process may be applied to a substrate that accounts for repeated, non-uniform chip-level photoresist patterns that are applied over a stress compensation layer.

To explain further the operations related to a non-uniform implant procedure for processing a stress compensation layer (SCL) in conjunction with a patterned gray tone resist layer, FIG. 1B shows further details of the controller 50. In this embodiment, the controller 50 may include a processor 52, such as a known type of microprocessor, dedicated processor chip, general purpose processor chip, or similar device. The controller 50 may further include a memory or memory unit 54, coupled to the processor 52, where the memory unit 54 contains a scanned implant routine 56. The scanned implant routine 56 may be operative on the processor 52 to manage an implant process using the ion beam 18 and substrate 100 in order to impart an implant pattern into a stress compensation layer, as discussed above. The memory unit 54 may comprise an article of manufacture. In one embodiment, the memory unit 54 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

In some implementations, the memory unit 54 may receive and/or store OPD information related to the substrate/stress compensation layer, as discussed above, for a given wafer or set of wafers. An example of OPD information may be a wafer surface map that is determined from an individual wafer or is characteristic of a batch of wafers. In some implementations, the memory unit may store information related to a gray tone resist pattern to be applied to a wafer or set of wafers. This information may be expressed in any suitable format including databases, tabular form, etc., and may include pre-stored gray tone resist patterns, pre-stored OPD patterns. Such information may then be used by the scanned implant routine 56 to calculate a best set of parameters to employ in an ion implantation process to manage OPD in a wafer being implanted. Such an ion implantation process will involve implanting an ion beam pattern into the substrate rather than a uniform ion beam, where a uniform ion beam may impart a uniform ion dose and uniform ion energy across a substrate, for example.

As an example, the information may be used to calculate a residual dose pattern of ions of a given energy and species to implant into the stress compensation layer, where the residual dose pattern is effective to smooth out the OPD. As such, the residual dose pattern may be determined by an application of the ion beam pattern to a resist pattern of the gray tone photoresist layer being implanted.

While the aforementioned embodiments focus upon the use of patterned resist layers in conjunction with ion implantation to selectively pattern a stress compensation layer in order to reduce substrate OPD, in other embodiments, a patterned resist layer may be used as an etch mask to facilitate selective etching of a stress compensation layer, as suggested in FIG. 3H. Moreover, the selective etching may be performed by an inert ion beam, a reactive ion beam, a radical beam, and so forth. This selective etching may be performed at the chip level in some embodiments, as illustrated for example, at FIG. 6A-6G. In some examples, selective etching may be accomplished by using a scanned beam in conjunction with a patterned stress compensation layer, including adjust beam scanning according to location of a given chip region on a substrate.

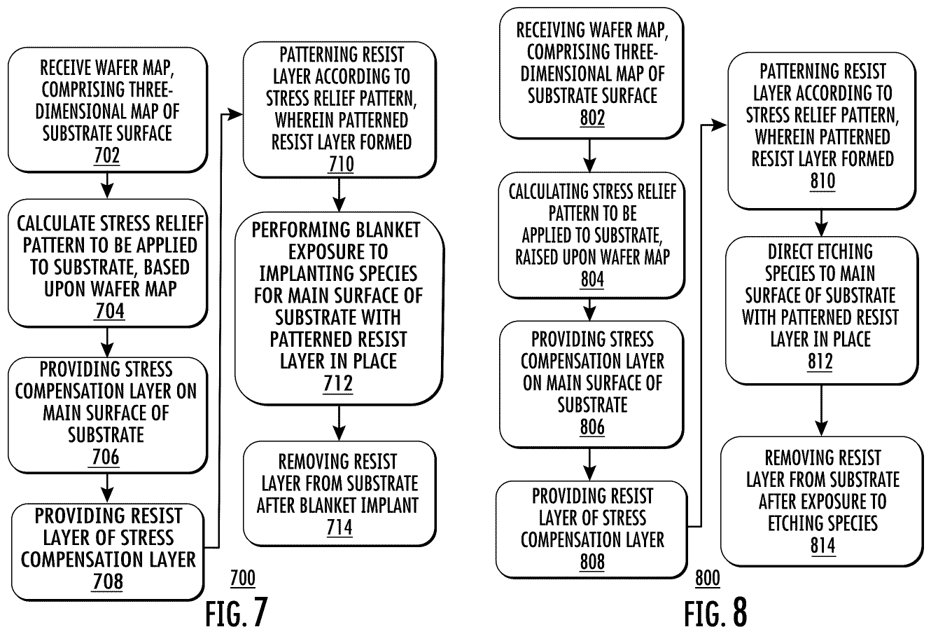

FIG. 7 illustrates an exemplary process flow. At block 702 a wafer map is received. The wafer map may correspond to a surface map that expresses a pattern of OPD across a substrate. The wafer map may correspond to the OPD on an existing substrate at a specific instance of processing.

At block 704, a stress relief pattern is calculated for applying to the substrate, based upon the wafer map. The stress relief pattern may be determined as an equivalent pattern of OPD modification, and may be further used to determine a pattern of ion implantation that will effectuate the OPD modification by implanting into a stress compensation layer. Such a pattern of ion implantation may take into account ion species, ion energy, ion dose, composition of the stress compensation layer, among other features. The stress relief pattern in particular will generate a map of ion dose to be imparted into a stress compensation layer as a function of position across a substrate.

At block 706, a stress compensation layer is provided on a main surface of the substrate. Note that this operation may be performed subsequently to the operation at block 704 or before the operation of block 704, or simultaneously.

At block 708 a resist layer is provided on the stress compensation layer. The resist layer may be a gray tone resist layer in some embodiments. In other embodiments, the resist layer may be a binary resist, or other known resist.

At block 710, the resist layer is patterned according to the stress relief pattern, so as to form a patterned resist layer. The patterning may be done using a gray tone mask to form a pattern of a region or a plurality of regions of varying resist thickness across the surface of the substrate that are designed to selectively transmit more or less ion dose into the stress compensation layer, according to the location on the main surface of the substrate. In some examples, the patterning may be performed according to a digital pattern where a series of resist lines are characterized by a line pitch, with a variable linewidth that is used to generate regions of different overall opacity of the resist. In other examples, an imprint mask having a desired pattern may be used to pattern the resist layer.

At block 712, a blanket exposure of the main surface of the substrate is conducted, where the blanket exposure directs implanting species to the main surface of the substrate with the patterned resist layer in place. The blanket exposure may be performed by scanning a substrate with respect to an inert ion beam or reactive ion beam, such as a ribbon beam, for example. In some embodiments, the blanket exposure may result in implantation of species such as energetic ions that are selectively implanted into the stress compensation layer in regions of lesser thickness or zero thickness of the resist layer.

At block 714, the resist layer is removed from the substrate after the blanket implant.

FIG. 8 illustrates another exemplary process flow 800. At block 802 a wafer map is received. The wafer map may correspond to a surface map that expresses a pattern of OPD across a substrate. The wafer map may correspond to the OPD on an existing substrate at a specific instance of processing.

At block 804, a stress relief pattern is calculated for applying to the substrate, based upon the wafer map. The stress relief pattern may be determined as an equivalent pattern of OPD modification, and may be further used to determine a pattern of ion implantation that will effectuate the OPD modification by implanting into a stress compensation layer. Such a pattern of ion implantation may take into account ion species, ion energy, ion dose, composition of the stress compensation layer, among other features. The stress relief pattern in particular will generate a map of ion dose to be imparted into a stress compensation layer as a function of position across a substrate.

At block 806, a stress compensation layer is provided on a main surface of the substrate. Note that this operation may be performed subsequently to the operation at block 804 or before the operation of block 804, or simultaneously.

At block 808 a resist layer is provided on the stress compensation layer. The resist layer may be a gray tone resist layer in some embodiments. In other embodiments, the resist layer may be a binary resist, or other known resist.

At block 810, the resist layer is patterned according to the stress relief pattern, so as to form a patterned resist layer. The patterning may be done to form a pattern of a region or a plurality of regions of varying resist thickness across the surface of the substrate that are designed to selectively transmit more or less ion dose into the stress compensation layer, according to the location on the main surface of the substrate. In some examples, the patterning may be performed according to a digital pattern where a series of resist lines are characterized by a line pitch, with a variable linewidth that is used to generate regions of different overall opacity of the resist.

At block 812, an exposure to etching species is performed, where the etching species are directed to the main surface of the substrate with the patterned gray tone resist layer in place. The etching species may be performed by scanning a substrate with respect to an ion beam or radical beam, such as a ribbon beam, for example. In other embodiments, the etching species may be provided by an exposure to ions and/or radicals in a plasma, including in a plasma immersion chamber. In some embodiments, the blanket exposure may result in the selective etching of regions of the stress compensation layer where a lesser thickness or zero thickness of resist layer is present.

At block 814, the resist layer is removed from the substrate after the blanket implant.

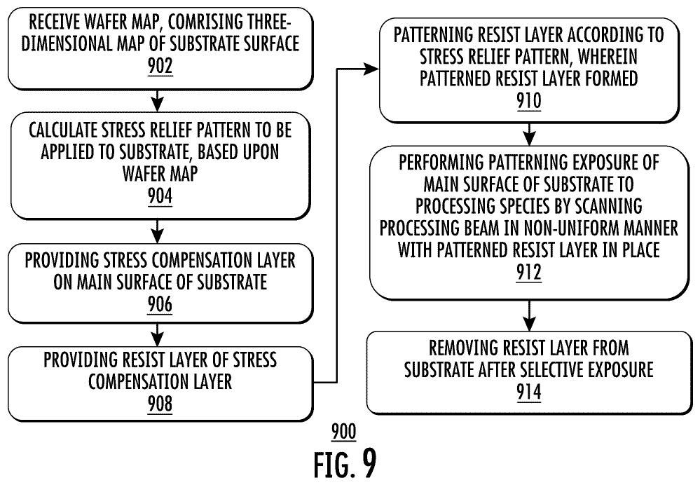

FIG. 9 illustrates another exemplary process flow 900. At block 902 a wafer map is received. The wafer map may correspond to a surface map that expresses a pattern of OPD across a substrate. The wafer map may correspond to the OPD on an existing substrate at a specific instance of processing.

At block 904, a stress relief pattern is calculated for applying to the substrate, based upon the wafer map. The stress relief pattern may be determined as an equivalent pattern of OPD modification, and may be further used to determine a pattern of ion implantation that will effectuate the OPD modification by implanting into a stress compensation layer. Such a pattern of ion implantation may take into account ion species, ion energy, ion dose, composition of the stress compensation layer, among other features. The stress relief pattern in particular will generate a map of ion dose to be imparted into a stress compensation layer as a function of position across a substrate.

At block 906, a stress compensation layer is provided on a main surface of the substrate. Note that this operation may be performed subsequently to the operation at block 804 or before the operation of block 804, or simultaneously.

At block 908 a resist layer is provided on the stress compensation layer. The resist layer may be a gray tone resist layer in some embodiments. In other embodiments, the resist layer may be a binary resist, or other known resist.

At block 910, the resist layer is patterned according to the stress relief pattern, so as to form a patterned resist layer. The patterning may be done to form a pattern of a region or a plurality of regions of varying resist thickness across the surface of the substrate that are designed to selectively transmit more or less ion dose into the stress compensation layer, according to the location on the main surface of the substrate. In some examples, the patterning may be performed according to a digital pattern where a series of resist lines are characterized by a line pitch, with a variable linewidth that is used to generate regions of different overall opacity of the resist.

At block 912, a patterning exposure of the main surface to processing species takes place, by scanning a processing beam in a non-uniform manner with respect to the substrate. The processing beam may be scanned with respect to a stationary substrate in one implementation, while the substrate may be scanned with respect to a stationary processing beam in another implementation. In a further implementation, scanning of both the processing beam and substrate may take place. The processing species may be an inert ion beam or reactive ion beam that is used to selective vary the ion dose of implanting species as a function of position across the main surface. Alternatively, the processing species may be a reactive ion beam or radical beam that is used to selectively vary the flux of ion or radical etching species as a function of position across the main surface of the substrate. The patterning exposure takes place while the patterned resist is in place. As such, the combination of the patterning exposure and the patterned resist layer may generate a targeted pattern of implantation or pattern of etching in the stress compensation layer, subjacent to the patterned resist layer.

At block 914, the resist layer is removed from the substrate after the patterning exposure.

Advantages provided by the present embodiments are multifold. As a first advantage, with the aid of a patterned gray tone resist layer or digitally patterned resist layer, a relatively simple ion implantation procedure may reduce a two dimensional OPD pattern over a substrate. As another advantage, because a fine scale pattern of ion implantation into a substrate may be defined by the pattern formed in a gray tone resist layer or digitally patterned resist layer, as opposed to the controlling of an ion beam to write an implant pattern into a wafer, relatively finer control of local OPD variation is possible. In other words, the resist layer may be patterned to generate varying ion dose into a stress compensation layer at least down to the micrometer length scale over a substrate surface. This type of dose variation control over a substrate surface may not be accomplished by scanning of ion beams whose size is on the order of centimeters. As a further advantage, management of complex patterns of OPD, such as chip level OPD patterns may be accomplished by generating a pattern in a resist layer to match the OPD patterns, using either a blanket exposure to a processing species or a patterned exposure, such as to a scanned ion beam or scanned radical beam.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of stress management in a substrate, comprising:
providing a stress compensation stack on a main surface of the substrate, wherein the stress compensation stack comprises a patterned resist layer and a stress compensation layer, disposed subjacent the patterned resist layer, the patterned resist layer being determined according to a surface map of the main surface of the substrate; and
directing processing species to the stress compensation stack, wherein the stress compensation layer is selectively altered as a function of position across the substrate.

2. The method of claim 1, wherein the patterned resist layer comprises:
a gray tone photoresist layer having a resist pattern that is characterized by a variable resist layer thickness as a function of location across a main surface of the substrate.

3. The method of claim 2, wherein the processing species are provided in an ion implantation procedure that comprises exposing the substrate to an ion beam that provides a uniform ion dose and uniform ion energy across the substrate, wherein at least a portion of the uniform ion dose is selectively blocked by the resist pattern.

4. The method of claim 3, wherein the ion implantation procedure comprises scanning the ion beam with respect to the substrate, wherein ion beam pattern is implanted into the substrate, the ion beam pattern comprising a varying ion dose as a function of position across the substrate.

5. The method of claim 4, wherein a residual dose pattern is implanted into the stress compensation layer, the residual dose pattern being determined by an application of the ion beam pattern to the resist pattern of the gray tone photoresist layer.

6. The method of claim 1, wherein the patterned resist layer has a variable thickness that is determined according to a three dimensional surface map of the main surface of the substrate.

7. The method of claim 2, wherein the gray tone photoresist layer is formed by:
depositing a blanket photoresist layer on the stress compensation layer;
performing an exposure of the blanket photoresist layer to illumination that is directed through a gray tone mask that is constructed according to the resist pattern; and
developing the blanket photoresist layer after the exposure.

8. The method of claim 2, wherein the gray tone photoresist layer is formed by:
depositing a blanket photoresist layer on the stress compensation layer; and
imprinting the blanket photoresist layer according to an imprint mask that is constructed according to the resist pattern.

9. The method of claim 1, wherein the processing species are provided by exposing the substrate to a uniform dose of etching species across the substrate, wherein at least a portion of the uniform dose of etching species is selectively blocked by the patterned resist layer from etching the stress compensation layer.

10. The method of claim 1, wherein the patterned resist layer is digitally-patterned resist layer.

11. An ion implanter, comprising:
an ion source to generate an ion beam;
a beamline component to vary a scanning of the ion beam; and
a controller, the controller comprising:
a processor; and
a memory unit coupled to the processor, including a scanned implant routine, the scanned implant routine operative on the processor to control the ion implanter to:
receive a surface map of a substrate; and
impart an implant pattern into a stress compensation layer on the substrate by performing a scanned implant based upon the surface map.

12. The ion implanter of claim 11, wherein the substrate further includes a gray tone resist, disposed on the stress compensation layer, wherein the scanned implant routine is further operative to calculate the implant pattern based upon a resist pattern in the gray tone resist.

13. The ion implanter of claim 12, wherein the resist pattern in the gray tone resist is determined by the surface map of the substrate.

14. The ion implanter of claim 11, wherein the resist pattern is a digital resist pattern.

15. The ion implanter of claim 11, wherein the surface map comprises a pattern of chip level variation in out-of-plane distortion, and wafer level variation in out-of-plane distortion.

16. A controller for an ion implanter, comprising:
a processor; and
a memory unit coupled to the processor, including a scanned implant routine, the scanned implant routine operative on the processor to control an ion implanter to:
receive a surface map of a substrate; and
impart an implant pattern into a stress compensation layer on the substrate by performing a scanned implant based upon the surface map.

17. The controller of claim 16, wherein the substrate further includes a gray tone resist, disposed on the stress compensation layer, wherein the scanned implant routine is further operative to calculate the implant pattern based upon a resist pattern in the gray tone resist.

18. The controller of claim 16, wherein the resist pattern in the gray tone resist is determined by the surface map of the substrate.

19. The controller of claim 17, wherein the resist pattern is a digital resist pattern.

20. The ion implanter of claim 16, wherein the surface map comprises a pattern of chip level variation in out-of-plane distortion, and wafer level variation in out-of-plane distortion.
